(19) United States
(12) Patent Application Publication
(10) Pub. No.: US 2024/0332145 A1
(43) Pub. Date: Oct. 3, 2024

(54) CLIPS WITH ALIGNMENT FEATURES AND RELATED METHODS

(71) Applicant: SEMICONDUCTOR COMPONENTS INDUSTRIES, LLC, Scottsdale, AZ (US)

(72) Inventors: Roxanna Samson Caguioa, Baguio City (PH); Aaron Alabin Bitavarra, Biñan (PH); Creed Lagdameo, Muntinlupa City (PH); Victor Aguinaldo, JR., Mabalacat (PH)

(73) Assignee: SEMICONDUCTOR COMPONENTS INDUSTRIES, LLC, Scottsdale, AZ (US)

(21) Appl. No.: 18/194,811

(22) Filed: Apr. 3, 2023

(51) Int. Cl. H01L 23/498; H01L 21/48; H01L 21/56; H01L 23/31

(52) U.S. Cl. CPC H01L 23/49805; H01L 21/486; H01L 21/563; H01L 21/565; H01L 23/3114

(57) ABSTRACT

Implementations of a clip for a semiconductor package may include at least a first thinned portion coupled with a main portion, the at least first thinned portion extending in a first direction away from the main portion; and at least a second thinned portion coupled with the main portion, the at least second thinned portion extending in a second direction away from the main portion. The first direction may oppose the first direction and the at least first thinned portion may be configured to engage with a first thinned portion of a leadframe and the at least second thinned portion may be configured to engage with a second thinned portion of the leadframe to align the main portion in a desired orientation relative to the leadframe.

### BACKGROUND

### 1. Technical Field

Aspects of this document relate generally to clips, such as clips for semiconductor packages.

### 2. Background

Semiconductor packages have been devised to allow various semiconductor die to electrically connect with a socket, circuit board, or motherboard to which the package is attached. Semiconductor packages also have been structured to protect semiconductor die from humidity or electrostatic discharge.

### SUMMARY

Implementations of a clip for a semiconductor package may include at least a first thinned portion coupled with a main portion, the at least first thinned portion extending in a first direction away from the main portion; and at least a second thinned portion coupled with the main portion, the at least second thinned portion extending in a second direction away from the main portion. The first direction may oppose the first direction and the at least first thinned portion may be configured to engage with a first thinned portion of a leadframe and the at least second thinned portion may be configured to engage with a second thinned portion of the leadframe to align the main portion in a desired orientation relative to the leadframe.

Implementations of a clip for a semiconductor package may include one, all, or any of the following:

The at least first thinned portion and the at least second thinned portion may be half etched.

The at least first thinned portion and the at least second thinned portion may be downset from the main portion.

The at least first thinned portion and the least second thinned portion may be configured to be located outside an outline of a package that may include the clip.

The at least first thinned portion and the at least second thinned portion may be coupled with at least one lead of the main portion.

The at least first thinned portion and the at least second thinned portion may be coupled with an alignment portion coupled with at least one lead of the main portion.

Implementations of a clip for a semiconductor package may include at least a first alignment portion coupled with a main portion, the at least first alignment portion extending away from the main portion; and at least a second alignment portion coupled with the main portion, the at least second alignment portion extending away from the main portion. The at least first alignment portion may be configured to engage with a first alignment slot of a leadframe and the at least second alignment portion may be configured to engage with a second alignment slot of the leadframe to align the main portion in a desired orientation relative to the leadframe.

Implementations of a clip for a semiconductor package may include one, all, or any of the following:

The at least first alignment portion and the at least second alignment portion may be downset from the main portion.

The at least first alignment portion and the least second alignment portion may be configured to be located outside an outline of a package that may include the clip.

The at least first alignment portion and the at least second alignment portion may be coupled with at least one lead of the main portion.

The at least first alignment portion and the at least second alignment portion may be coupled with an alignment portion coupled with at least one lead of the main portion.

The at least first alignment portion and the at least second alignment portion may be each a portion of a lead of the main portion.

The at least first alignment portion and the at least second alignment portion include a thickness that may be the same as a thickness of the leadframe.

The first alignment slot and the second alignment slot may be configured to receive an end of the at least first alignment portion and an end of the at least second alignment portion, respectively.

Implementations of a method of assembling a semiconductor package may include providing a clip including one of at least a first alignment portion and at least second alignment portion coupled with a main portion, the at least first alignment portion and the at least second alignment portion extending away from the main portion; at least a first thinned portion and at least a second thinned portion coupled with the main portion, the at least first thinned portion extending in a first direction away from the main portion and the at least second thinned portion extending in a second direction away from the main portion; or any combination thereof. The method may also include attaching a semiconductor die to a leadframe and engaging one of the at least first alignment portion and the at least second alignment portion with a first alignment slot and with a second alignment slot of the leadframe respectively; the at least first thinned portion and the at least second thinned portion with a first thinned portion of a leadframe and with a second thinned portion of the leadframe, respectively; or any combination thereof. The method may also include molding a mold compound over the semiconductor die, at least a portion of the leadframe, and at least a portion of the clip; and trimming the leadframe and the clip to form a plurality of leads.

Implementations of a method of assembling a semiconductor package may include one, all, or any of the following:

The at least first alignment portion, the at least second alignment portion, the at least first thinned portion, and the at least second thinned portion may be downset from the main portion.

The at least first alignment portion, the least second alignment portion, the at least first thinned portion, and the at least second thinned portion may be configured to be located outside an outline of the semiconductor package.

The at least first thinned portion and the at least second thinned portion may be coupled with at least one lead of the main portion.

The at least first alignment portion and the at least second alignment portion may be each a portion of a lead of the main portion.

The leadframe may include a first alignment slot and a second alignment slot that receive an end of the at least first alignment portion and an end of the at least second alignment portion during the engaging, respectively.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a perspective view of an implementation of a clip;

FIG. 2 is a perspective view of an implementation of a leadframe with a semiconductor die attached thereto;

FIG. 3 is a detail perspective view of an alignment portion of a clip implementation engaged with a leadframe along with two detail views of thinned portions of the clip and the leadframe;

FIG. 4 is a perspective partial see through view of a leadframe, clip, and semiconductor implementation with mold compound applied thereto;

FIG. 5 is a perspective partial see through view of a semiconductor package implementation following trimming/singulation;

FIG. 6 is a side partial see through view of a semiconductor package implementation showing downset leads;

FIG. 7 is a top partial see through view of a clip implementation showing the outline of an applied mold compound;

FIG. 8 is a top partial see through view of a clip implementation showing the outline of an applied mold compound; and

FIG. 9 is a perspective partial see through view of a semiconductor package implementation with fused leads.

### DESCRIPTION

This disclosure, its aspects and implementations, are not limited to the specific components, assembly procedures or method elements disclosed herein. Many additional components, assembly procedures and/or method elements known in the art consistent with the intended clips with alignment features will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such clips with alignment features, and implementing components and methods, consistent with the intended operation and methods.

Clips are often used to provide electrical connection to a side of a semiconductor die that is not already contacted by a leadframe. For example, a leadframe may include a die flag portion to which the a surface of a semiconductor die is attached during assembly, but the leadframe cannot reach the opposing surface of the semiconductor die. In such a situation, a clip can be used to provide electrical connection(s) to pads or other portions of the semiconductor die on the opposing surface of the semiconductor die. Clips can also be used as the primary electrical connection/mechanical support for a semiconductor die in a package.

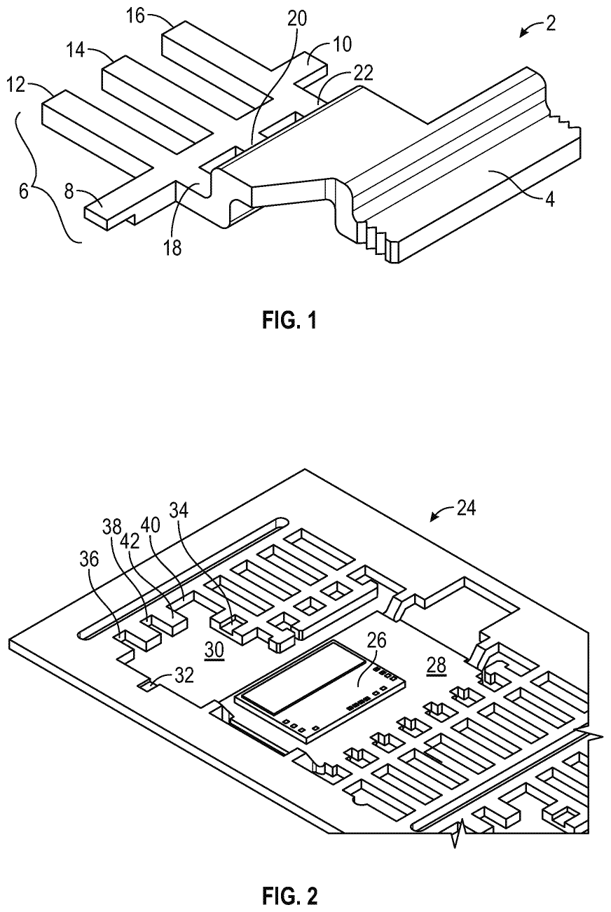

Referring to FIG. 1, an implementation of a clip 2 is illustrated. The clip 2 includes a main portion 4 designed to couple to a side of a semiconductor die and an alignment section 6. In this implementation of a clip, the alignment section 6 includes a first thinned portion 8 and a second thinned portion 10. The first thinned portion 8 extends away from the main portion 4/alignment section 6 in a first direction and the second thinned portion 10 extends away from the main portion 4/alignment section 6 in a second direction. In this implementation, the first direction and second direction are in opposing directions. However, in other implementations, the first direction and second direction may not be aligned 180 degrees from each other, but may be oriented 90 degrees from each other or may be aligned parallel with each other where the first thinned portion and second thinned portion are in a spaced apart relationship. While the implementation in FIG. 1 illustrates the use of two thinned portions, more than two thinned portions may be used in other clip implementations.

The clip 2 also includes three alignment portions 12, 14, 16 that extend away from the main portion 4. As illustrated, each of the three alignment portions 12, 14, 16 are coupled to portions of the clip 2 that will eventually become leads 18, 20, 22 when singulated. As illustrated in FIG. 1, the three alignment portions 12, 14, 16 can also be described as being a portion of each of the leads 18, 20, 22 prior to being singulated/cut away in various other steps. While the inclusion of the three alignment portions 12, 14, 16 as part of the leads 18, 20, 22 is illustrated in the clip implementation of FIG. 1, in other implementations, any or all of the alignment portions may not be part of one, any, or all of the leads.

In the clip 2 implementation illustrated in FIG. 1, the first thinned portion 8, the second thinned portion 10, and the three alignment portions 12, 14, 16 are all downset from the main portion 4. This is because the main portion 4 of this particular clip is designed to accommodate the thickness of the semiconductor die when the clip is coupled thereto. In other implementations, however, if the ultimate alignment of the leads of the clip can be at the level of the semiconductor die, then the first and second thinned portions and the three alignment portions may not be downset from the main portion. This situation may also occur where the die flag/die support of the leadframe is adjusted to a depth so that the leads of the clip do not need to be below the level of the upper/opposing surface of the semiconductor die when packaged. In implementations where the clip is the primary mechanical support for the die, the leads may or may not be downset. A wide variety of possible alignments of the thinned portions and the alignment portions are possible using the principles disclosed herein.

The clip 2 implementation illustrated in FIG. 1 includes both first and second thinned portions 8, 10 and alignment portions 12, 14, 16. However, in various implementations, only two thinned portions may be included and no alignment portions may be included. In other implementations, only two alignment portions may be included and no thinned portions may be included. In yet other implementations, only one thinned portion and only one alignment portion may be included. Many possible combinations of thinned portion(s) and alignment portion(s) in various clip implementations may be constructed using the principles disclosed herein. These may also be constructed to accommodate various leadframe implementations as well.

Referring to FIG. 2, an implementation of a leadframe 24 is illustrated. Here semiconductor die 26 has been attached to die flag 28 which is illustrated as being downset relative to a plane formed by the rest of the leadframe 24. An opening 30 is illustrated adjacent to the die flag 28 into which the alignment portion of a clip can be placed. The leadframe 24 also includes thinned portions 32, 34 which are designed to receive two corresponding thinned portions of a clip implementation. In various implementations, the thinned portions of the leadframe and the clip may be thinned by half etching. In other implementations, however, the thinned portions may be formed using other methods, including, by non-limiting example, stamping, punching, casting, cutting, or any other method of removing material from an electrically conductive substrate. Also, leadframe 24 includes three slots 36, 38, 40 which are designed to receive ends of the alignment portions of a clip. Note that the slots 36, 38, 40 are not all the same size, nor may one or more of the slots be sized to accommodate all of the dimensions of the ends of the alignment portions. Here, slot 40 is larger than the end of the alignment portion 16 of the clip of FIG. 16, but because it is spaced on one side to correspond with the spacing between the alignment portions, the projection 42 between slots 38 and 40 fits between the alignment portions 14, and 16.

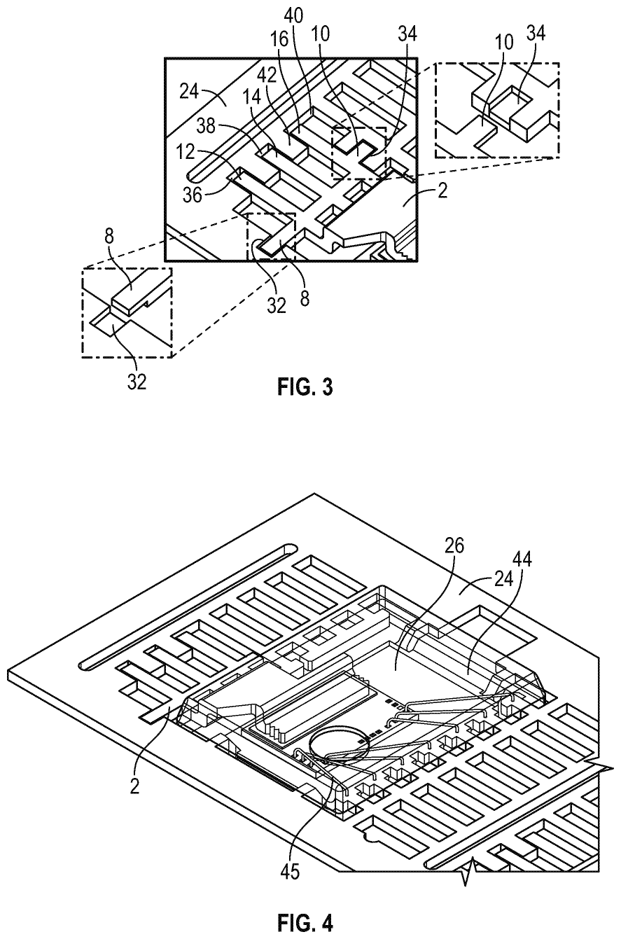

FIG. 3 illustrates this relationship in a detail view along with magnified exploded views of the relationship between the thinned portions 32, 34 of the leadframe 24 and the thinned portions 8, 10 of the clip 2. Note that in the implementation of FIG. 3, the alignment of the clip 2 does not require that the slots 36, 38, 40 be precisely dimensioned to correspond with the ends of the alignment portions 12, 14, 16, but a gap/space exists between the ends of the alignment portions 12, 14, 16 and the slots 36, 38, 40. This is because the engagement of the thinned portions 8, 10 into the thinned portions 32, 34 of the leadframe 24 sets the distance the alignment portions 12, 14, 16 slide into the slots 36, 38, 40. This ability to use the thinned portions to set the alignment of the clip a specified distance along the alignment portions 12, 14, 16 demonstrates the clip alignment capabilities present when both thinned portions and alignment portions are used in an alignment portion of a clip. In this way the thinned portions and alignment portions work together to prevent movement of the clip in X and Y during assembly operations because they work together to lock the clip in the desired position above the semiconductor die.

This same ability to prevent movement of the clip in X and Y can be achieved with using only thinned portions or only alignment portions, however. However, the combination of both the thinned portions and alignment portions can help provide a robust alignment solution for various combinations of clip and leadframe designs. While the use of two thinned portions 8, 10 with three alignment portions 12, 14, 16 is illustrated in FIGS. 1-3, more or fewer of each could be included depending on how many leads are associated with clip 2 and/or the desired degree of stability for the clip when placed into the alignment opening in the leadframe.

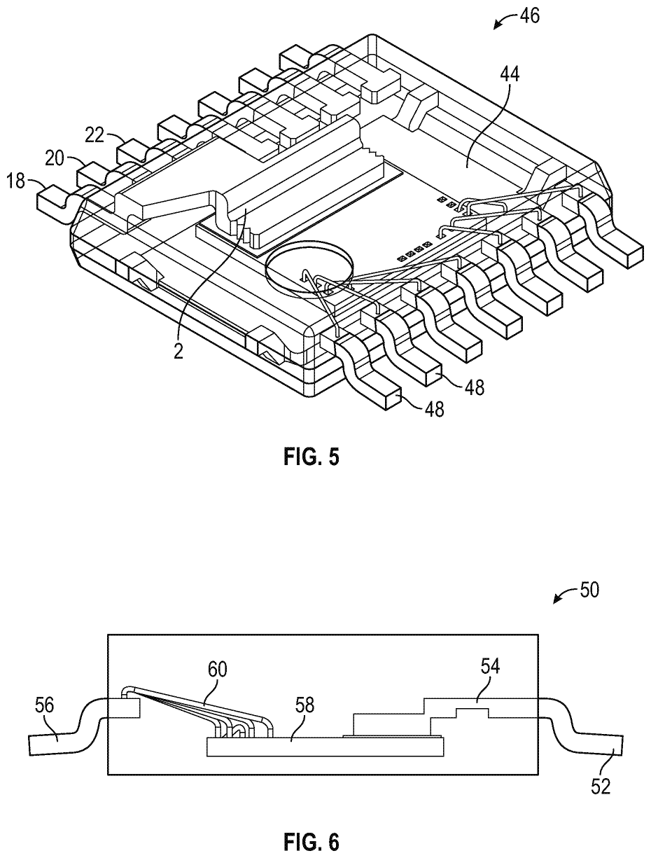

Referring to FIG. 4, the implementation of the leadframe 24 and clip 2 of FIGS. 1-3 are illustrated following application/formation of a mold compound 44 and the formation of various wirebonds 45 to desired bond pads on the semiconductor die 26. The wirebonds 45 are designed to couple the bond pads on the semiconductor die with various of the leads on the leadframe. FIG. 5 is a partial see through view of the semiconductor package 46 formed following singulation/cutting of the leads 48 from the leadframe 24 and those leads 18, 20, 22 from the clip 2. In the package implementation illustrated in FIG. 5, the package is a leaded package, i.e., the package has leads that extend from the sidewalls formed by the mold compound 44 and are used to bond the package to a circuit board or motherboard using soldering and/or insertion. However, the package could also be a “no-lead” package design where the leads are cut flush or substantially flush with the sidewalls of the mold compound 44 and then soldered to bond the package to a circuit board or motherboard. In such no-lead package designs, the leads are present, but do not extend from the surface(s) of the mold compound.

FIG. 6 is a side partial see through view of a semiconductor package implementation 50 showing how the leads 52 of the clip 54 are directly connected to the top of the die and the leads 56 of the leadframe used are coupled by wirebonding to the semiconductor die 58 through wirebonds 60. Mold compound encapsulates the semiconductor die 58 and portions of the clip 54 and of the leads 56 from the leadframe.

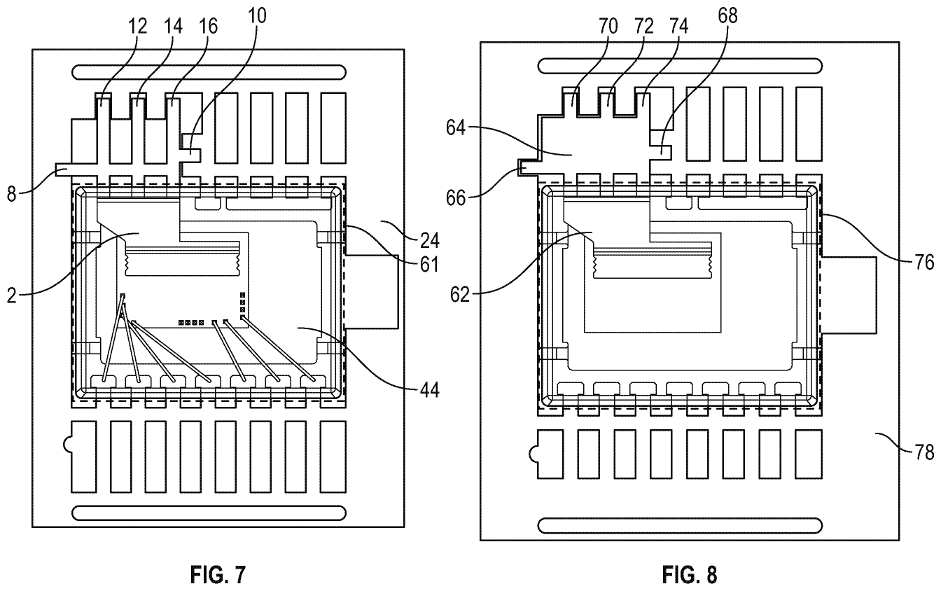

FIG. 7 is a top view of the clip 2, leadframe 24, and mold compound 44 implementation of FIG. 4 showing the relationship between the thinned portions 8, 10 and the alignment portions 12, 14, 16 of the clip 2. This view shows how the thinned portions 8, 10 and alignment portions 12, 14, and 16 are outside of the outline of the package (and the mold compound 44) indicated by dotted line 61. A similar result is illustrated in the clip implementation 62 of FIG. 8 which includes a solid alignment section 64 in the form of an island from which thinned portions 66, 68 and alignment portions 70, 72, 74 project. Again, the alignment section 64 with the corresponding thinned portions 66, 68, and alignment portions 70, 72, 74 are all outside the outline of the package as indicated by the dotted line 76 from leadframe 78. In both of the package implementations 2, 62 of FIGS. 7 and 8, during the final formation steps, the ends of the leads are first cut to the desired length by punching, then bent into a gull wing shape. At that point, the package is finally singulated by cutting the remaining portions holding the package to the leadframe. In these implementations, because the leads extend beyond the finished outline of the package, they can be formed into a gull wing shape in this way, or left straight or otherwise bent as desired depending on the particular insertion used to fasten the package to a motherboard or other circuit board. The ability to use alignment features in the clip that are not included in the leads of the final package can greatly enhance the flexibility of the design of these features for the clip and/or particular leadframe designs.

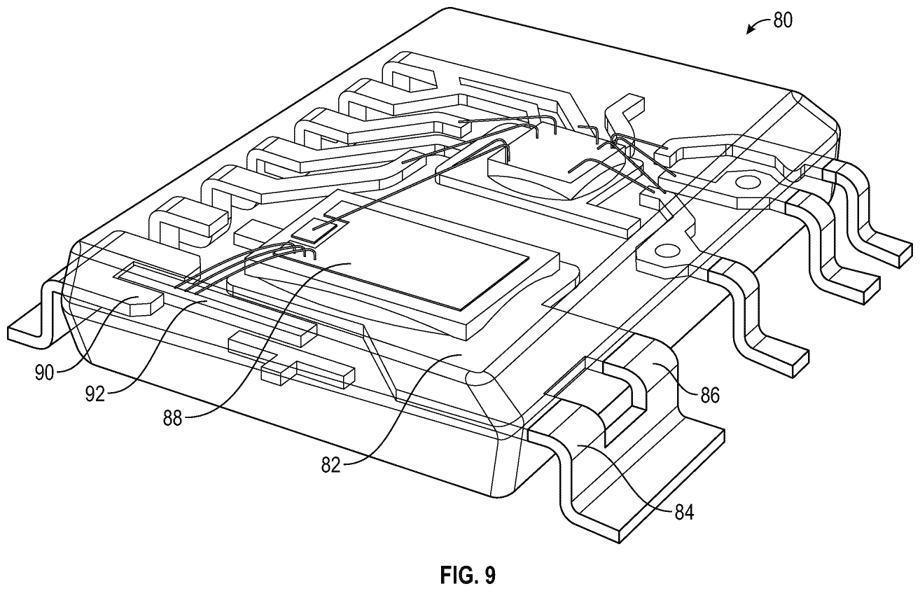

In the various clip implementations discussed thus far, the leads of the clip have been illustrated as being separate from each other, each providing a separate electrical connection to the clip. However, referring to FIG. 9, in other implementations, the clip or other portion of the leadframe may include fused or connected leads. FIG. 9 illustrates a semiconductor package 80 that includes a die flag 82 that has two leads 84, 86 that are fused after being cut/trimmed. The principles disclosed herein can be used for clip designs where the clip does not overlap a portion of the leadframe and is the only or major support for the semiconductor die in the finished package. FIG. 9 also illustrates clip 90 that was designed to align around a connecting bar 92 of the leadframe and includes a single large lead. In this case, the alignment of the clip can be created through accommodating features of the leadframe rather than for the leadframe accommodating features of the clip. FIG. 9 illustrates examples of the wide variety of structural possibilities that exist for the various clip designs disclosed in this document that involve single, fused, or large leads of various kinds. For example, in the package implementation 62 of FIG. 8, the solid alignment section 64 can be used to form fused leads simply by leaving the solid alignment section in place following the initial lead cutting/punching operation through the bending operation. The resulting gull wing structure then becomes a fused lead similar to the two leads 84, 86 of FIG. 9. Many different possibilities for lead structures and shapes are possible using the principles disclosed herein.

The materials used for the various leadframes and clips may be any of a wide variety of materials, such as, by non-limiting example, metals, metal alloys, copper, aluminum, copper alloys, aluminum alloys, or any other electrically conductive materials. These materials may be formed using a wide variety of methods, including, by non-limiting example, punching, stamping, bending, casting, three-dimensional printing, electroplating, or any other method of shaping/forming/solidifying the material of the leadframe or clip.

The various clip and leadframe implementations disclosed herein may be utilized in various implementations of methods of assembling a semiconductor package. In the various method implementations, the method includes attaching a semiconductor die to a leadframe and coupling a clip to the semiconductor die. Attaching the semiconductor die and coupling the clip to the semiconductor die may involve using a die attach material on either or both of the leadframe and the clip. The method also may include engaging at least a first and a second alignment portions coupled with a main portion of the clip with a corresponding first and second alignment slots of the leadframe. The method may also include engaging at least a first and a second thinned portion with a corresponding at least first and second thinned portions of the leadframe. In various method implementations, any combination of engaging alignment portion(s), thinned portion(s) or both alignment portion(s) and thinned portion(s) may be utilized depending on the particular structural design of the clip and leadframe implementations used, which may be any previously disclosed in this document.

The method implementations may also include molding a mold compound over the semiconductor die, a portion of the leadframe, and a portion of the clip. While the use of mold compounds has been disclosed in this document, in some package implementations, no mold compound may be used as in immersion cooled semiconductor package designs. The method also includes trimming/cutting/singulating/lead forming the leadframe and the clip to form a plurality of leads. The lead forming operations may include one or more bending steps, including gull wing bending in various method implementations. The resulting leads may be any disclosed in this document including fused leads in various method implementations. A wide variety of method implementations may be created using the principles disclosed herein.

In places where the description above refers to particular implementations of clips with alignment features and implementing components, sub-components, methods and sub-methods, it should be readily apparent that a number of modifications may be made without departing from the spirit thereof and that these implementations, implementing components, sub-components, methods and sub-methods may be applied to other clips with alignment features.

What is claimed is:

1. A clip for a semiconductor package, the clip comprising:
at least a first thinned portion coupled with a main portion, the at least first thinned portion extending in a first direction away from the main portion; and
at least a second thinned portion coupled with the main portion, the at least second thinned portion extending in a second direction away from the main portion;
wherein the first direction opposes the first direction; and
wherein the at least first thinned portion is configured to engage with a first thinned portion of a leadframe and the at least second thinned portion is configured to engage with a second thinned portion of the leadframe to align the main portion in a desired orientation relative to the leadframe.

2. The clip of claim 1, wherein the at least first thinned portion and the at least second thinned portion are half etched.

3. The clip of claim 1, wherein the at least first thinned portion and the at least second thinned portion are downset from the main portion.

4. The clip of claim 1, wherein the at least first thinned portion and the least second thinned portion are configured to be located outside an outline of a package that comprises the clip.

5. The clip of claim 1, wherein the at least first thinned portion and the at least second thinned portion are coupled with at least one lead of the main portion.

6. The clip of claim 1, wherein the at least first thinned portion and the at least second thinned portion are coupled with an alignment portion coupled with at least one lead of the main portion.

7. A clip for a semiconductor package, the clip comprising:
at least a first alignment portion coupled with a main portion, the at least first alignment portion extending away from the main portion; and
at least a second alignment portion coupled with the main portion, the at least second alignment portion extending away from the main portion;
wherein the at least first alignment portion is configured to engage with a first alignment slot of a leadframe and the at least second alignment portion is configured to engage with a second alignment slot of the leadframe to align the main portion in a desired orientation relative to the leadframe.

8. The clip of claim 7, wherein the at least first alignment portion and the at least second alignment portion are downset from the main portion.

9. The clip of claim 7, wherein the at least first alignment portion and the least second alignment portion are configured to be located outside an outline of a package that comprises the clip.

10. The clip of claim 7, wherein the at least first alignment portion and the at least second alignment portion are coupled with at least one lead of the main portion.

11. The clip of claim 7, wherein the at least first alignment portion and the at least second alignment portion are coupled with an alignment portion coupled with at least one lead of the main portion.

12. The clip of claim 7, wherein the at least first alignment portion and the at least second alignment portion are each a portion of a lead of the main portion.

13. The clip of claim 7, wherein the at least first alignment portion and the at least second alignment portion comprise a thickness that is the same as a thickness of the leadframe.

14. The clip of claim 7, wherein the first alignment slot and the second alignment slot are configured to receive an end of the at least first alignment portion and an end of the at least second alignment portion, respectively.

15. A method of assembling a semiconductor package, the method comprising:
providing a clip comprising one of:
at least a first alignment portion and at least second alignment portion coupled with a main portion, the at least first alignment portion and the at least second alignment portion extending away from the main portion;
at least a first thinned portion and at least a second thinned portion coupled with the main portion, the at least first thinned portion extending in a first direction away from the main portion and the at least second thinned portion extending in a second direction away from the main portion; or
any combination thereof;
attaching a semiconductor die to a leadframe;
engaging one of:
the at least first alignment portion and the at least second alignment portion with a first alignment slot and with a second alignment slot of the leadframe respectively;
the at least first thinned portion and the at least second thinned portion with a first thinned portion of a leadframe and with a second thinned portion of the leadframe, respectively; or
any combination thereof;
molding a mold compound over the semiconductor die, at least a portion of the leadframe, and at least a portion of the clip; and
trimming the leadframe and the clip to form a plurality of leads.

16. The method of claim 15, wherein the at least first alignment portion, the at least second alignment portion, the at least first thinned portion, and the at least second thinned portion are downset from the main portion.

17. The method of claim 15, wherein the at least first alignment portion, the least second alignment portion, the at least first thinned portion, and the at least second thinned portion are configured to be located outside an outline of the semiconductor package.

18. The method of claim 15, wherein the at least first thinned portion and the at least second thinned portion are coupled with at least one lead of the main portion.

19. The method of claim 15, wherein the at least first alignment portion and the at least second alignment portion are each a portion of a lead of the main portion.

20. The method of claim 15, wherein the leadframe comprises a first alignment slot and a second alignment slot that receive an end of the at least first alignment portion and an end of the at least second alignment portion during the engaging, respectively.
